(19) United States
(12) Patent Application Publication
(10) Pub. No.: US 2013/0260510 A1
(43) Pub. Date: Oct. 3, 2013

(54) 3-D Integrated Circuits and Methods of Forming Thereof

(71) Applicant: Horst Theuss, Wenzenbach (DE)

(72) Inventor: Horst Theuss, Wenzenbach (DE)

(73) Assignee: INFINEON TECHNOLOGIES AG, Neubiberg (DE)

(21) Appl. No.: 13/437,409

(22) Filed: Apr. 2, 2012

(51) Int. Cl. H01L 21/78

(52) U.S. Cl. 438/109; 257/E21.502; 257/E21.599

(57) ABSTRACT

In one embodiment, a method of forming a semiconductor device includes stacking a second wafer with a first wafer and forming a through via extending through the second wafer while the second wafer is stacked with the first wafer. In another embodiment, a method of forming a semiconductor device includes singulating a first wafer into a first plurality of dies and attaching the first plurality of dies over a second wafer having a second plurality of dies. The method further includes forming a through via extending through a die of the first plurality of dies after attaching the first plurality of dies over the second wafer.

### TECHNICAL FIELD

The present invention relates generally to semiconductor devices, and, in particular embodiments, to three dimensional (3-D) integrated circuits and methods of forming them.

### BACKGROUND

Semiconductor devices are used in many electronic and other applications. Semiconductor devices comprise integrated circuits that are formed on semiconductor wafers.

Semiconductor devices are manufactured by depositing many different types of material layers over a semiconductor workpiece or wafer, and patterning the various material layers using lithography. The material layers typically comprise thin films of conductive, semiconductive, and insulating materials that are patterned and etched to form integrated circuits (ICs). There may be a plurality of transistors, memory devices, switches, conductive lines, diodes, capacitors, logic circuits, and other electronic components formed on a single die or chip, for example.

After an integrated circuit is manufactured, individual die are singulated from the wafer, and typically, the die is packaged. For many years, the most common way of packaging a die was horizontal placement within individual plastic or ceramic packages. Alternatively, several die may be packaged horizontally in a single package, forming a multi-chip module. Electrical connections are made to terminals or bond pads of the die, e.g., using very small strands of wire, which is routed to pins of the package.

A demand for smaller ICs with higher performance has led to the development of system-on-a-chip devices, where portions of the chip are dedicated to memory and other portions are dedicated to logic or other types of circuitry. However, it can be difficult to manufacture an IC with multiple types of circuitry, due to integration problems of the different circuit fabrication technologies.

One trend in the semiconductor industry is the movement towards three dimensional integrated circuits (3D-ICs), for example, where two or more chips or wafers are stacked and vertically integrated. Parts of a circuit are fabricated on different wafers, and the wafers or die are bonded together with a glue layer such as copper or a polymer based adhesive. Different types of circuits, e.g., memory and logic, as examples, may be manufactured separately and then vertically attached, which may be less expensive and easier to manufacture than combining the two circuit technologies on a single wafer as in system-on-a-chip devices. 3D-ICs are predicted to be used in the future for low power, high speed applications, because the paths of conduction may be shortened by the vertical electrical connections between the circuits, resulting in low power consumption and increased speed.

Semiconductor device manufacturers are constantly striving to increase the performance of their products, while decreasing manufacturing costs. 3-D packaging is a cost intensive area in the fabrication of semiconductor devices because of the associated design and fabrication challenges.

### SUMMARY OF THE INVENTION

These and other problems are generally solved or circumvented, and technical advantages are generally achieved, by illustrative embodiments of the present invention.

In accordance with an embodiment of the present invention, a method of forming a semiconductor device comprises stacking a second wafer with a first wafer and forming a through hole that extends through the second wafer while the second wafer is stacked with the first wafer. The method further includes forming a through via by filling the through hole with a conductive material.

In accordance with another embodiment of the present invention, a method of forming a semiconductor device comprises providing a first reconstituted wafer comprising a first plurality of dies embedded within a first encapsulant and providing a second reconstituted wafer comprising a second plurality of dies embedded within a second encapsulant. The method further includes stacking the first reconstituted wafer with the second reconstituted wafer and forming a through via extending through the second reconstituted wafer. The through via is formed while the first reconstituted wafer remains stacked with the second reconstituted wafer.

In accordance with another embodiment of the present invention, a method of forming a semiconductor device comprises singulating a first wafer into a first plurality of dies and attaching the first plurality of dies over a second wafer comprising a second plurality of dies. The method further includes forming a through via extending through a die of the first plurality of dies after attaching the first plurality of dies over the second wafer.

The foregoing has outlined rather broadly the features of an embodiment of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawing, in which:

FIGS. 1-4 describe a method of forming stacked semiconductor dies having through substrate vias in accordance with embodiments of the invention;

FIGS. 5-7 illustrate an alternative embodiment of forming the stacked semiconductor devices using back-to-back joining and having through vias for interconnecting the dies;

FIGS. 8-11 illustrate an alternative embodiment of forming a stacked semiconductor device having through vias;

FIGS. 12-22 illustrate a fabrication of a stacked semiconductor device comprising a plurality of fan-out packages stacked over each and coupled using through substrate vias;

FIG. 23, which includes FIGS. 23A and 23B, illustrates a further embodiment of forming 3-D integrated fan-out package having a plurality of stacked dies;

FIG. 24, which includes FIGS. 24A-24E, illustrates a further embodiment of forming 3-D integrated packages having a plurality of stacked dies, wherein FIGS. 24A-24D illustrate fan-out packages while FIG. 24E illustrates stacked semiconductor chips;

FIG. 25 illustrates forming a lead frame package comprising stacked chip in accordance with embodiments of the invention; and

FIG. 26, which includes FIGS. 26A and 26B, illustrates flip-chip mounting of the stacked dies in various embodiments of the invention.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of various embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Embodiments of the invention overcome the problems of stacking a plurality of different chips into a single package thereby forming 3-D integrated circuits. Embodiments accomplish these using low cost through vias, which are formed globally over stacked wafers dramatically reducing processing costs. Rather than forming through vias on each die separately, embodiments of the invention form through vias simultaneously over a plurality of stacked wafers thus dramatically reducing processing costs.

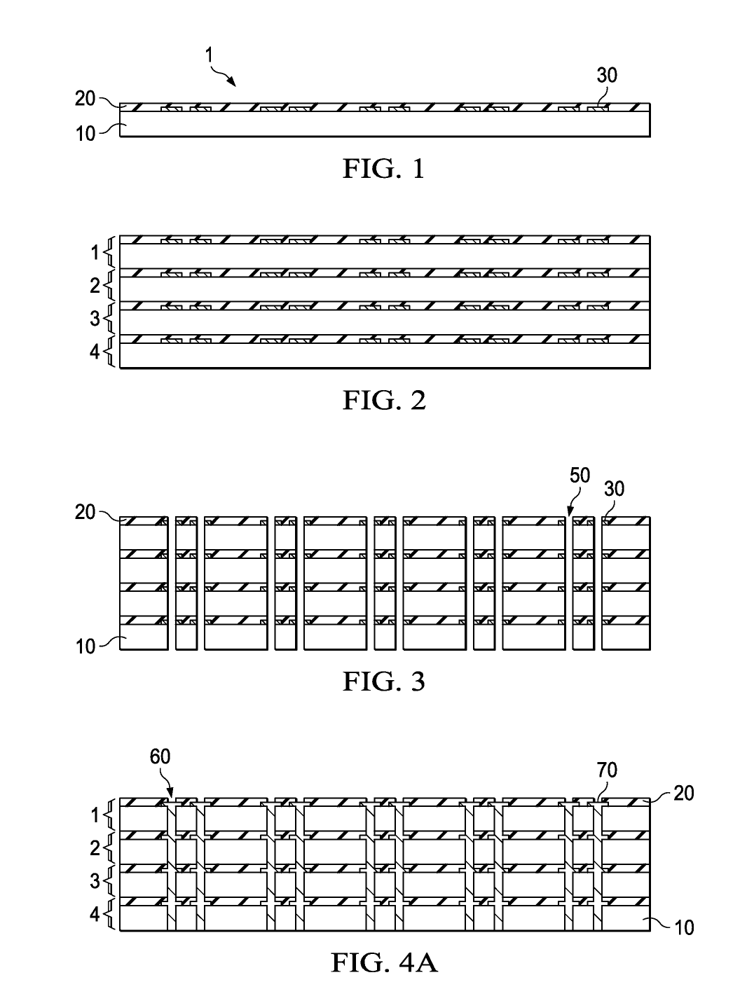

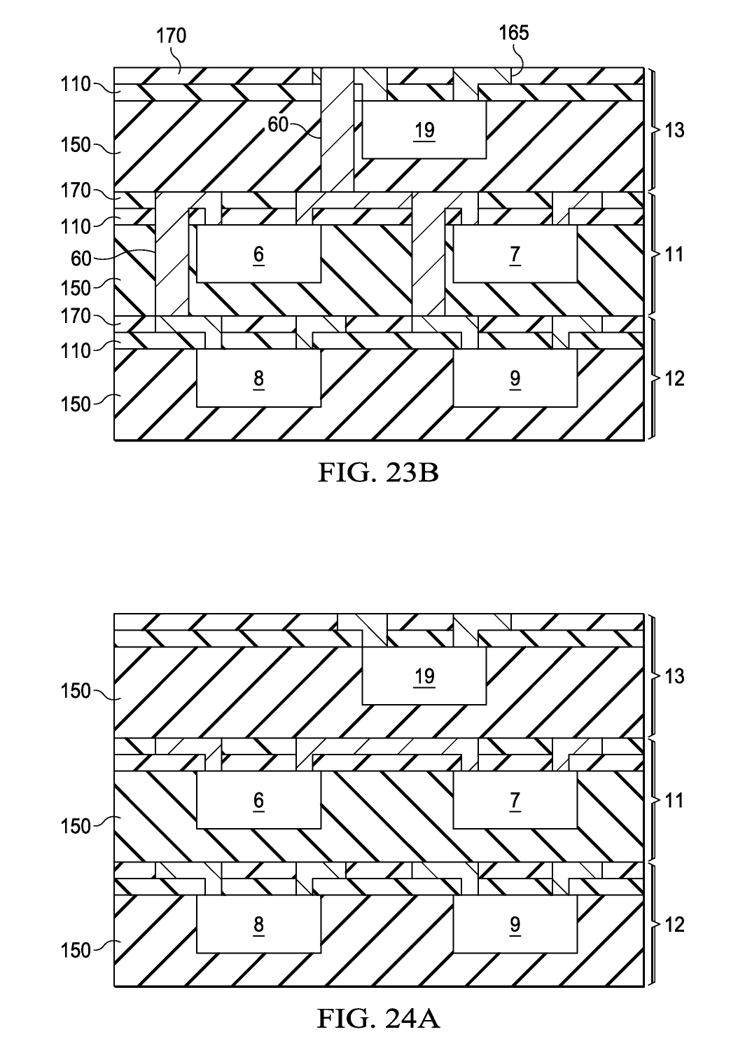

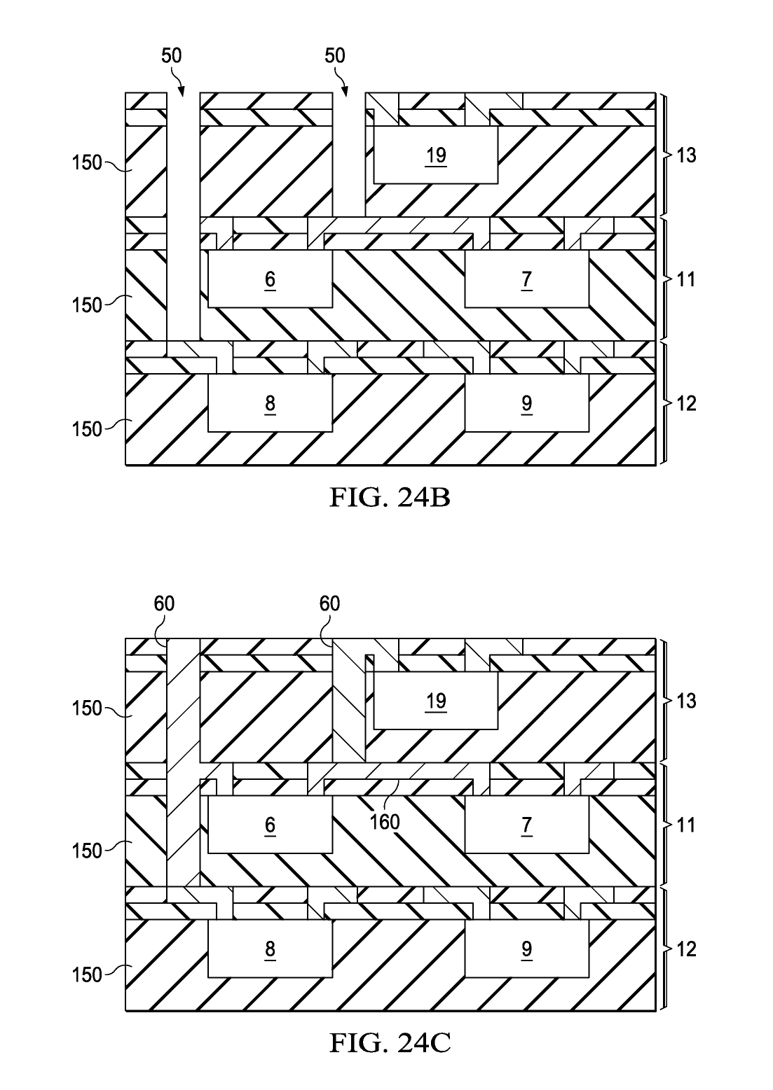

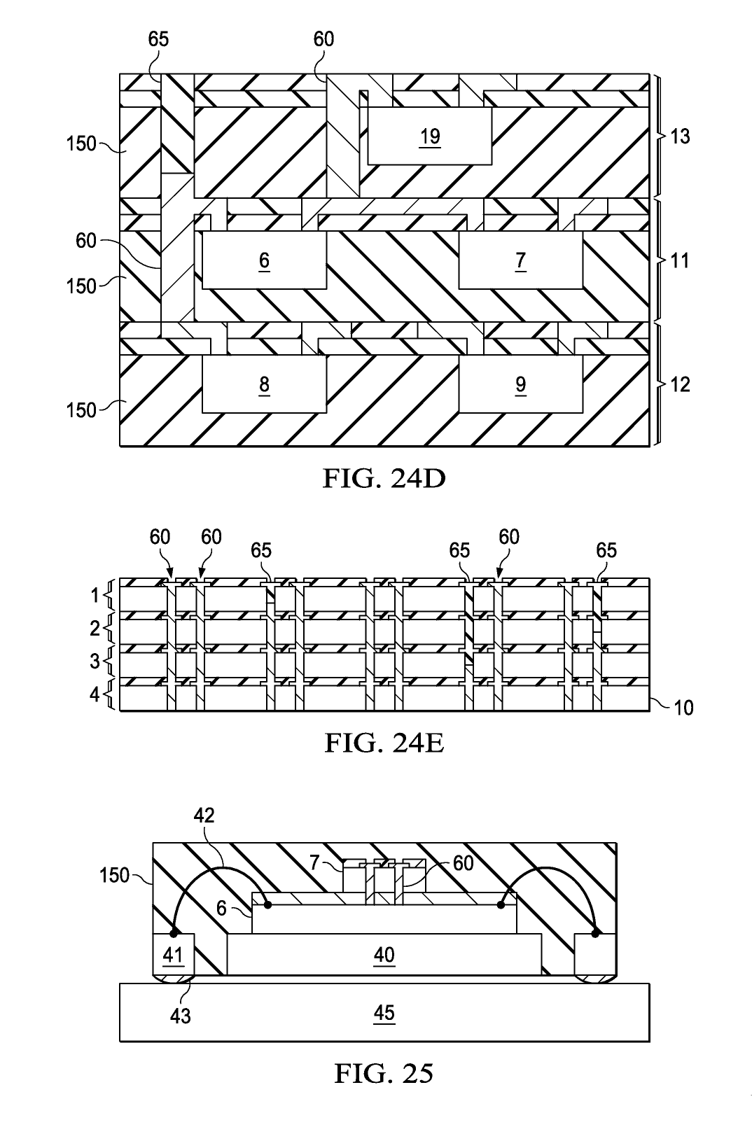

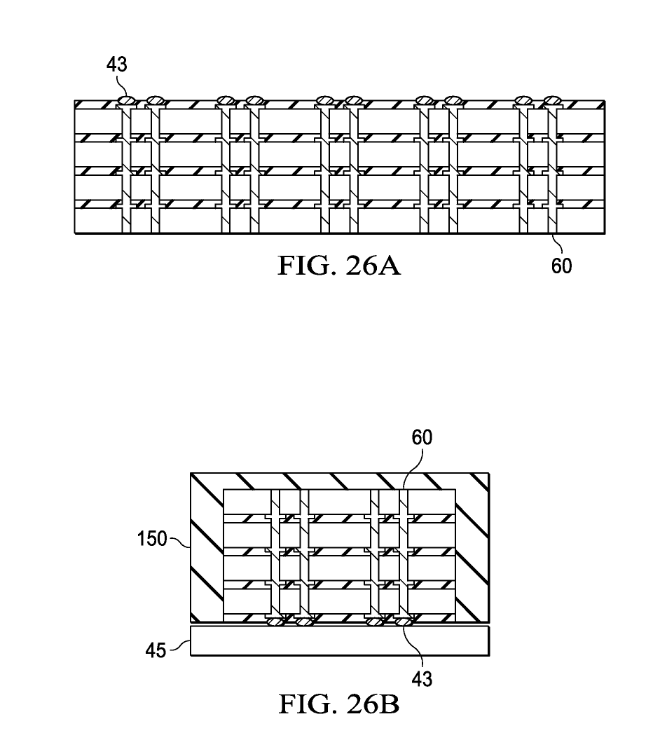

A method of fabricating a stacked semiconductor die will be described using FIGS. 1-4 in accordance with an embodiment of the invention. An alternative embodiment of fabricating a stacked back-to-back semiconductor dies will be described using FIGS. 5-7. Another alternative embodiment of fabricating stacked dies will be described using FIGS. 8-10. An alternative embodiment of forming stacked semiconductor packages using an embedded wafer level packaging process will be described using FIGS. 12-22. Further embodiments of forming stacked semiconductor packages using an embedded wafer level packaging process will be described using FIGS. 23 and 24. An embodiment of the invention applied to a leadframe package will be described using FIG. 25. An embodiment of the invention applied to a flip chip will be described using FIG. 26. As will be also described again features of the various embodiments may be combined together.

FIGS. 1-4 describe a method of forming stacked semiconductor dies having through substrate vias in accordance with embodiments of the invention.

FIG. 1 illustrates a substrate 10 having a plurality of dies after all front end and back end processing. Front end processing refers to the formation of active device regions while back end processing refers to the formation of metallization layers to interconnect the various devices of the integrated circuit. In other words, the first wafer 1 is a processed wafer having a plurality of dies including metallization formed therein. For example, in one or more embodiments, the substrate 10 comprises a wafer having an array of dies on a front side. In various embodiments, the substrate 10 may be silicon alloys and compound semiconductors. In some embodiments, the substrate 10 may be an III-V substrate with elements from Group III and Group V, or the substrate 10 may be an II-VI substrate with elements from Group II and Group VI. In one or more embodiments, the substrate 10 may be a silicon-on-sapphire (SOS) substrate. In one or more embodiments, the substrate 10 may be a germanium-on-insulator (GeOI) substrate. In one or more embodiments, the substrate 10 may include one or more semiconductor materials such as silicon, silicon germanium, germanium, gallium arsenide, indium arsenide, indium arsenide, gallium nitride, indium gallium arsenide, or indium antimonide.

The plurality of dies may comprise different type of dies including integrated circuits or discrete devices. In one or more embodiments, the plurality of dies in the substrate 10 may comprise logic chips, memory chips, analog chips, mixed signal chips, and combinations thereof such as system on chip. The plurality of dies may comprise various types of active and passive devices such as diodes, transistors, thyristors, capacitors, inductors, resistors, optoelectronic devices, sensors, microelectromechanical systems, and others.

Contacts 30 are formed for electrically connecting the dies to external sources. The contacts 30 may be coupled to the substrate 10 through interconnect metallization (not shown). A passivation or protective layer 20 is disposed on a front side of the substrate 10. The protective layer 20 may be an oxide (such as silicon dioxide) layer in one embodiment. The protective layer 20 may comprise other dielectric materials such as nitride, silicon oxynitride in other embodiments. Thus, the contacts 30 are disposed within the protective layer 20.

The substrate 10 is thinned from the back side. In various embodiments, the thickness of the substrate 10 after the thinning is about 20 μm to about 100 μm, and 80 μm to about 120 μm in one embodiment. In another embodiment, the thickness of the substrate 10 after the thinning is about 50 μm to about 100 μm. In another embodiment, the thickness of the substrate 10 after the thinning is about 20 μm to about 50 μm. In another embodiment, the thickness of the substrate 10 after the thinning is about 10 μm to about 20 μm. In another embodiment, the thickness of the substrate 10 after the thinning is at least 10 μm. In another embodiment, the thickness of the substrate 10 after the thinning is at least 20 μm. In another embodiment, the thickness of the substrate 10 after the thinning is at least 50 μm. In another embodiment, the thickness of the substrate 10 after the thinning is less than 100 μm. In another embodiment, the thickness of the substrate 10 after the thinning is less than 80 μm. In another embodiment, the thickness of the substrate 10 after the thinning is less than 50 μm. In another embodiment, the thickness of the substrate 10 after the thinning is less than 30 μm. The final thickness of the substrate 10 may be selected based on the mechanical stability, need for reducing resistances, and others.

Next, as illustrated in FIG. 2, a plurality of thinned substrates 10, for example a first wafer 1, a second wafer 2, a third wafer 3, and a fourth wafer 4 are stacked over each other. In various embodiments, the same type of wafer is stacked. For example, in one embodiment, the first wafer 1 and the second wafer 2 comprise memory chips. In an alternative embodiment, different types of wafer may be stacked. For example, in one embodiment, the first wafer 1 comprises logic chips while the second wafer 2 comprises memory chips. Similarly, in some embodiments, one of the wafers may comprise an analog chip while one of the other wafers comprises a logic chip or a memory chip. In one embodiment, a first wafer 1, a second wafer 2, a third wafer 3, and a fourth wafer 4 may be one or more of logic chips, memory chips, analog chips, mixed signal chips, and system on chips.

Advantageously, stacking thinned wafers provides the needed mechanical stability for subsequent processing. Further, the aspect ratios of openings for forming through vias are process compatible (because of the thinning).

The stack of wafers is joined using any suitable method. In one embodiment, an anodic bonding may be used. In alternative embodiments, direct bonding or intermediate layer bonding may be used. In direct or fusion bonding, the wafers are contacted directly without the assistance of significant pressure or any intermediate layers or field. In direct bonding, the surface of the wafers is prepared to ensure good contact, for example, the surface roughness and the wafer bow may be tightly controlled. In one case, the surface roughness of the wafers prior to bonding is less than 2 nm, and about less than 1 nm in one embodiment. Prior to bonding, the surfaces of the wafers are cleaned to remove particulate materials. The cleaned surfaces may become hydrophilic or hydrophobic. In some embodiments, a plasma may be used to clean and/or activate the surface prior to contacting. After contacting the wafers, the stacked wafers may be annealed. In one embodiment, the stacked wafers are annealed at a temperature of about 250° C. to about 320° C., and about 280° C. to about 300° C. in another embodiment.

In case of anodic bonding, a dielectric layer on one of the wafers bonds to the semiconductor region of the other wafer. For example, the protective layer 20 of the second wafer 2 is bonded to the semiconductor region of the substrate 10 of the first wafer 1. A potential difference is applied between the substrate 10 of the first wafer 1 and the protective layer 20 of the second wafer 2 and the stacked wafers are heated. Due to the higher temperatures and applied fields, a chemical bond forms between the substrate 10 of the first wafer 1 and the protective layer 20 of the second wafer 2. Alternatively, a glass layer may be sputtered over the protective layer 20 for the bonding with the substrate 10 of the first wafer 1. In various embodiments, the stacked wafers are heated to about 100° C. to about 400° C., and about 200° C. to about 300° C. in one embodiment.

In intermediate layer bonding, intermediate layers are used to join the wafers. Examples include use of glass frit joining, eutectic bonds, epoxy, polymers, solders, or thermo-compression bonds. In glass frit joining or glass soldering, a glassy formulation is applied on the surfaces of the wafers to be joined. Next, the stacked wafers are heated to a first temperature to about 100° C. to about 200° C., and about 100° C. to about 140° C. in one embodiment. The annealing may be used to remove the solvents from the glassy formulation. Next, the stacked wafers are heated to a second temperature to remove any organic materials. The second temperature may be about 200° C. to about 400° C., and about 250° C. to about 350° C. in one embodiment. In one embodiment, a single anneal at a higher temperature may be used instead of the two anneals described above. In a third annealing step, the wafer stack is annealed at a third temperature, which melts the glassy formulation. In one embodiment, a single anneal at a higher temperature may be used instead of the three anneals described above. Finally, the wafers are aligned and heated above the glass melting temperature again while they are squeezed together thereby forming the bond. In eutectic bonding, a eutectic material is deposited on one of the wafers (e.g., as a pattern) and the wafers are brought into contact and held above the eutectic temperature forming the eutectic, which forms the eutectic bond. Examples of eutectic bonding include solders.

Referring to FIG. 3, through openings 50 are formed through the stacked dies. In various embodiments, the through openings 50 may be formed using chemical etching processes such as deep reactive ion etching after a masking process to form a hard mask. In various embodiments, the through openings 50 may be formed using a Bosch Process or by depositing a hard mask layer and etching through the stacked wafers using a vertical reactive ion etch.

In the Bosch process, etching and deposition are alternatively performed and may be repeated many times. In a first step, a plasma etch is used to vertically etch an opening while in a second step a passivation layer is deposited so as to prevent widening of the opening in regions already etched. The plasma etch is configured to etch vertically, e.g., using sulfur hexafluoride [SF6] in the plasma. The passivation layer is deposited, for example, using octa-fluoro-cyclobutane as a source gas. Each individual step may be turned on for a few seconds or less. The passivation layer protects the substrate 10 so as to prevent lateral etching. However, during the plasma etching phase, the directional ions that bombard the substrate 10 remove the passivation layer at the bottom of the opening being formed (but not along the sides) and etching continues. The Bosch process may produce sidewalls that are scalloped.

The through openings 50 may also be formed using other processes such as using a laser. In some embodiments, mechanical processes may also be used to form the through openings 50. However, chemical processes may be used especially when the aspect ratios of the through openings 50 is large.

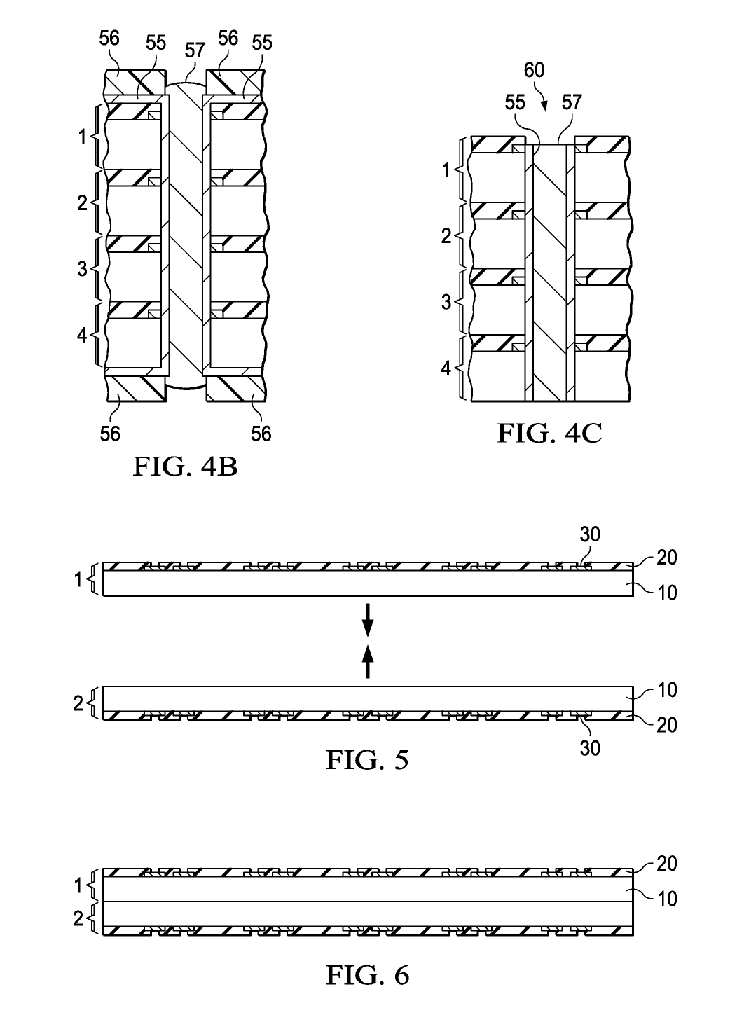

FIG. 4, which includes FIGS. 4A-4C, illustrates the formation of through vias in accordance with embodiments of the invention, wherein FIGS. 4B and 4C illustrate a magnified cross-sectional view of a through via formed using an electroplating process.

As next illustrated in FIG. 4A, through vias 60 are formed within the through openings 50 of the stacked wafers. The through vias 60 may be formed using any convenient process including electroplating, electroless plating, sputtering, printing, coating, deposition, and others. In electro-less plating, the stacked wafers are immersed in a plating bath. Thus, both sides of the stacked wafers are exposed to the plating bath and therefore processed at once.

Alternatively in one embodiment, and referring to FIG. 4B, an electroplating process may be used. In such an embodiment, a seed layer 55 may be formed over the top surface and the opposite bottom surface of the stacked wafers. The seed layer 55 may be formed using a metal deposition process such as sputtering, vapor deposition processes including chemical vapor deposition (CVD), plasma vapor deposition (PVD). The seed layer 55 may be formed over the entire surface as a blanket layer in one or more embodiments. The seed layer 55 may comprise titanium, tantalum, tungsten, hafnium, molybdenum, ruthenium, tantalum nitride, titanium nitride, tungsten nitride, carbides thereof, and combinations thereof.

A resist 56 may be formed covering the seed layer 55 over areas that are not to be plated. Alternatively, the seed layer 55 may be removed from the top and bottom surfaces of the stacked wafers. A fill material 57 is plated within the through openings 50 using an electroplating process. The fill material 57 may comprise copper in one embodiment. The fill material 57 may comprise pure copper or alloys of copper. In other embodiments, the fill material 57 comprises silver, gold, platinum, nickel, zinc, and others. The electroplating process does not grow over the covered seed layer 55 and only over the exposed seed layer 55.

After electroplating, as illustrated in FIG. 4C, the resist 56 is removed, for example, using an etching process. Next, the exposed seed layer 55 is etched thereby forming the through vias 60.

In one or more embodiments, the through vias 60 may be formed by applying a liquid, paste, or a solder. In one embodiment, the through vias 60 may be applied as conductive particles in a polymer matrix. In an alternative embodiment, a conductive nano-paste such as a silver nano-paste may be applied. In various embodiments, any suitable material including metals or metal alloys such as aluminum, titanium, gold, silver, copper, palladium, platinum, nickel, chromium or nickel vanadium, may be used to form the through vias 60.

Additional contact pads 70 may be formed for contacting the through vias 60. In one or more embodiments, the contact pads 70 may comprise deposition of materials suitable for subsequent formation of solders.

Unlike conventional processes, embodiments of the invention form the through vias after stacking wafers. In contrast, in conventional processes through vias are formed before die stacking.

FIGS. 5-7 illustrate an alternative embodiment of forming the stacked semiconductor devices using back-to-back joining and having through vias for interconnecting the dies.

Front side processing is performed as in the prior embodiments. After completing the front side processing, the wafers are thinned from the back side. The wafers may be thinned using a grinding process, a chemical process, or a chemical mechanical process.

As illustrated in FIG. 5, the back side of the first wafer 1 is brought together with the back side of the second wafer 2. Unlike the prior embodiments, the surfaces of the substrate 10, which are made of the same material type, are made to contact each other. For example, in one case, silicon surface of the first wafer 1 is made to contact with the silicon surface of the second wafer 2. Thus, this embodiment is more amenable to direct bonding and anodic bonding techniques described previously. Stacking the wafers back-to-back allows for denser integration of through vias.

As next illustrated in FIG. 6, the first wafer 1 and the second wafer 2 are made to contact and are joined together forming a stacked wafer. Embodiments of the invention may use any suitable method for wafer bonding including methods described above in prior embodiments.

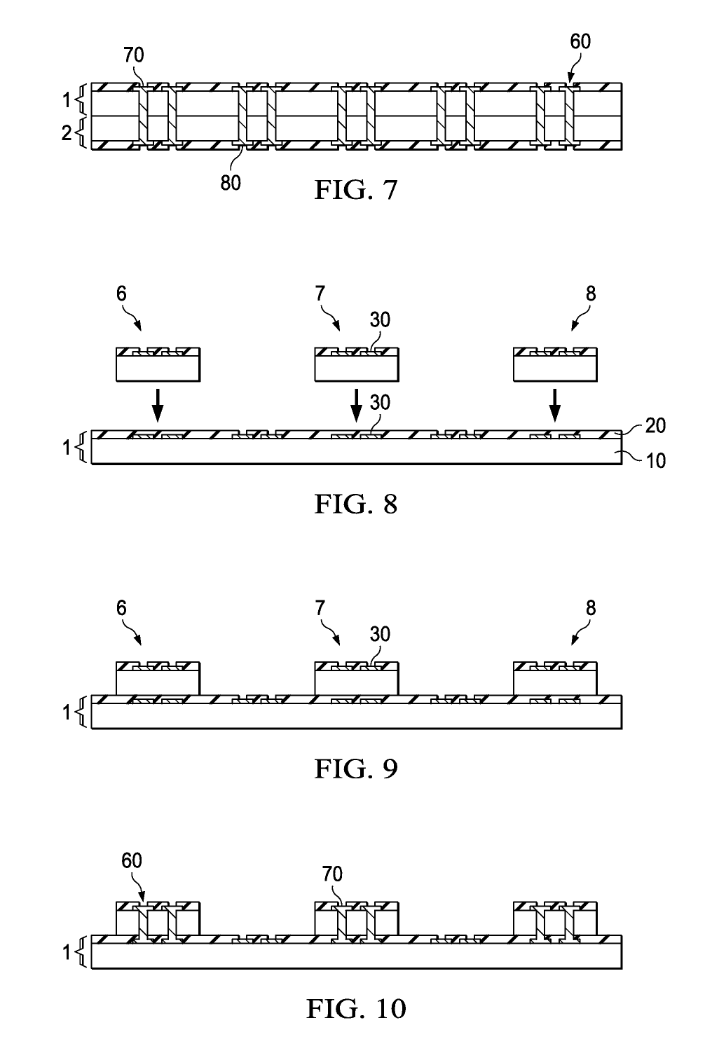

Referring to FIG. 7, through vias 60 having contact pads 70 are formed as described previously. As in the prior embodiment, through openings are formed within the stacked wafer (after stacking and joining the wafers) and the through openings are filled with a conductive material to form the through vias 60.

FIGS. 8-11 illustrate an alternative embodiment of forming a stacked semiconductor device having through vias.

In this embodiment, a plurality of dies may be stacked over a wafer. Therefore, this embodiment describes die-to-wafer stacking in contrast to wafer-to-wafer stacking described in prior embodiments. Thus, as illustrated in FIG. 8, a first die 6 may be stacked over a first wafer 1 comprising a die. As described previously, the first wafer 1 is a processed wafer having a plurality of dies including metallization formed therein. The metallization and active devices are protected using a top protective layer 20. The first wafer 1 includes contacts 30 for forming external contacts.

Similarly, a second die 7 is stacked over another die of the first wafer 1 and a third die 8 is stacked over the first wafer 1. Embodiments of the invention include stacking multiple dies over the wafer. For example, another die may be stacked over the first die 6 forming a stacking of three or more dies. In various embodiments, the dies may be stacked back-to-back as in FIGS. 5-7 or face-to-back as in FIGS. 1-4. In back-to-back configuration, the back side of the first die 6 (opposite the front side adjacent the active device and having protective layer 20 and contacts 30) is contacted with the corresponding back side of the first wafer 1.

As in prior embodiments, the first die 6 may be a different or same type of die than the dies of the first wafer 1.

Referring to FIG. 9, the plurality of dies is attached to the first wafer 1. The attaching may be performed using any suitable process for bonding dies to a substrate. Examples include intermediate layer bonding described above as well as anodic bonding and direct bonding if possible. In one or more embodiments, anodic bonding may be used when attaching the plurality of dies to the first wafer 1 using the back-to-back configuration.

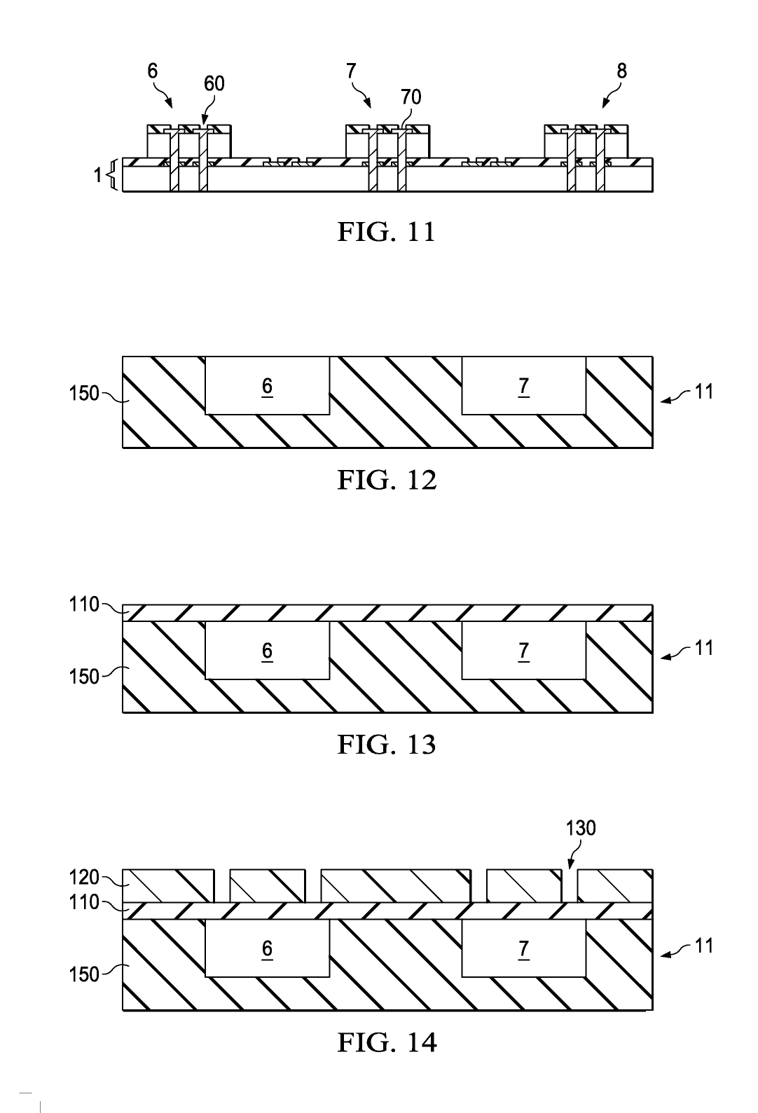

Referring to FIG. 10, the through vias 60 are formed within the plurality of dies. In some embodiments, the through vias 60 may be formed within both the plurality of dies and the first wafer 1 as illustrated in FIG. 11.

After forming the through vias 60, the first wafer 1 is singulated. In some embodiments, the first wafer 1 may be thinned from the back side and then singulated. In other words, the first wafer 1 may be thinned prior to attaching the plurality of dies in some embodiments especially when the plurality of dies is thin so that no stability issues arise during the formation of the through vias 60. Alternatively, for providing stability during formation of the through vias 60, the thinning of the first wafer 1 may be performed after forming the through vias 60.

FIGS. 12-22 illustrate a fabrication of a stacked semiconductor device comprising a plurality of fan-out packages stacked over each and coupled using through substrate vias.

Embodiments of the invention may be applied to fan-out packages. Embedded wafer level packaging is an enhancement of the standard wafer level packaging in which the packaging is realized on an artificial wafer. A standard wafer is diced and the singulated chips are placed on a carrier. The distances between the chips on the carrier may be chosen freely. The gaps around the chips may be filled with an encapsulation material to form an artificial wafer. The artificial wafer is processed to manufacture packages comprising the chips and a surrounding fan-out area. Interconnect elements may be realized on the chip and the fan-out area forming an embedded wafer level ball grid array (eWLB) package.

In a fan-out type package at least some of the external contact pads and/or conductor lines connecting the semiconductor chip to the external contact pads are located laterally outside of the outline of the semiconductor chip or at least intersect the outline of the semiconductor chip. Thus, in fan-out type packages, a peripherally outer part of the package of the semiconductor chip is typically (additionally) used for electrically bonding the package to external applications, such as application boards, etc. This outer part of the package encompassing the semiconductor chip effectively enlarges the contact area of the package in relation to the footprint of the semiconductor chip, thus leading to relaxed constraints in view of package pad size and pitch with regard to later processing, e.g., second level assembly.

FIG. 12 illustrates an embedded wafer level packaged wafer (also referred as reconstituted wafer). The reconstituted wafer 11 is formed by arranging singulated dies over a carrier and encapsulating the dies with an encapsulating material 150, which protects and seals the dies.

In one embodiment, the encapsulating material 150 is applied using a compression molding process. In compression molding, the encapsulating material 150 may be placed into a molding cavity, then the molding cavity is closed to compress the encapsulating material 150. Compression molding may be used when a single pattern is being molded. In an alternative embodiment, the encapsulating material 150 is applied using a transfer molding process.

In other embodiments, the encapsulating material 150 may be applied using injection molding, granulate molding, powder molding, or liquid molding. Alternatively, the encapsulating material 150 may be applied using printing processes such as stencil or screen printing.

In various embodiments, the encapsulating material 150 comprises a dielectric material and may comprise a mold compound in one embodiment. In other embodiments, the encapsulating material 150 may comprise a polymer, a biopolymer, a fiber impregnated polymer (e.g., carbon or glass fibers in a resin), a particle filled polymer, and other organic materials. In one or more embodiments, the encapsulating material 150 comprises a sealant not formed using a mold compound, and materials such as epoxy resins and/or silicones. In various embodiments, the encapsulating material 150 may be made of any appropriate duroplastic, thermoplastic, or thermosetting material, or a laminate. The material of the encapsulating material 150 may include filler materials in some embodiments. In one embodiment, the encapsulating material 150 may comprise epoxy material and a fill material comprising small particles of glass or other electrically insulating mineral filler materials like alumina or organic fill materials.

The encapsulating material 150 may be cured, i.e., subjected to a thermal process to harden thus forming a hermetic seal protecting the dies such as the first die 6 and the second die 7.

A first dielectric layer 110 may be deposited as illustrated in FIG. 13. The first dielectric layer 110 may comprise an oxide or nitride material such as silicon oxide or silicon nitride.

As next illustrated in FIG. 14, a resist 120 is deposited over the first dielectric layer 110 and patterned to form openings 130. The resist 120 may comprise a photo resist as well as hard mask material such as silicon nitride, silicon carbide, or combinations. The resist 120 may comprise a plurality of layers in various embodiments.

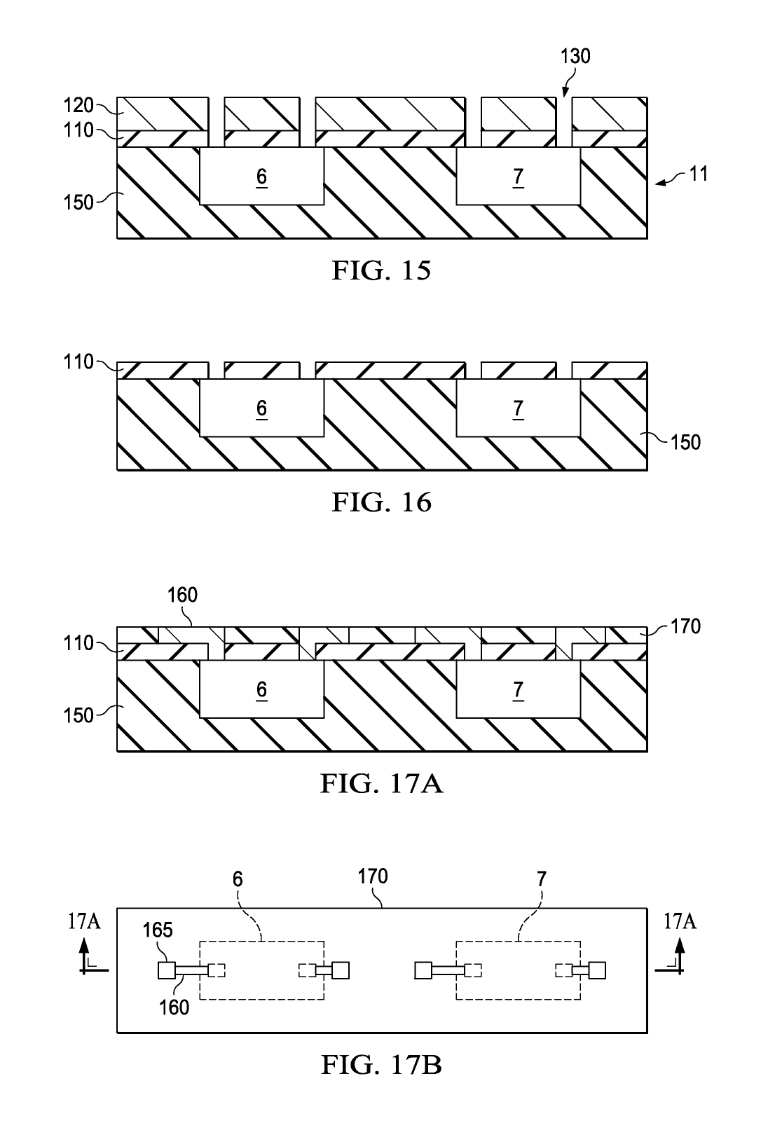

Using the resist 120 as a mask, the first dielectric layer 110 may be patterned as shown in FIG. 15. The resist 120 may be removed as illustrated in FIG. 16. Next, a plurality of redistribution lines 160 and embedded contact pads 165 are formed as shown in FIGS. 17, which includes FIG. 17A and 17B. A second dielectric layer 170 may optionally be used to protect the contact pads 165.

Thus, a fan-out embedded wafer or a reconstituted wafer having redistribution lines and embedded contact pads 165 is formed. In various embodiments, any other suitable design and process may be used to form the reconstituted wafer.

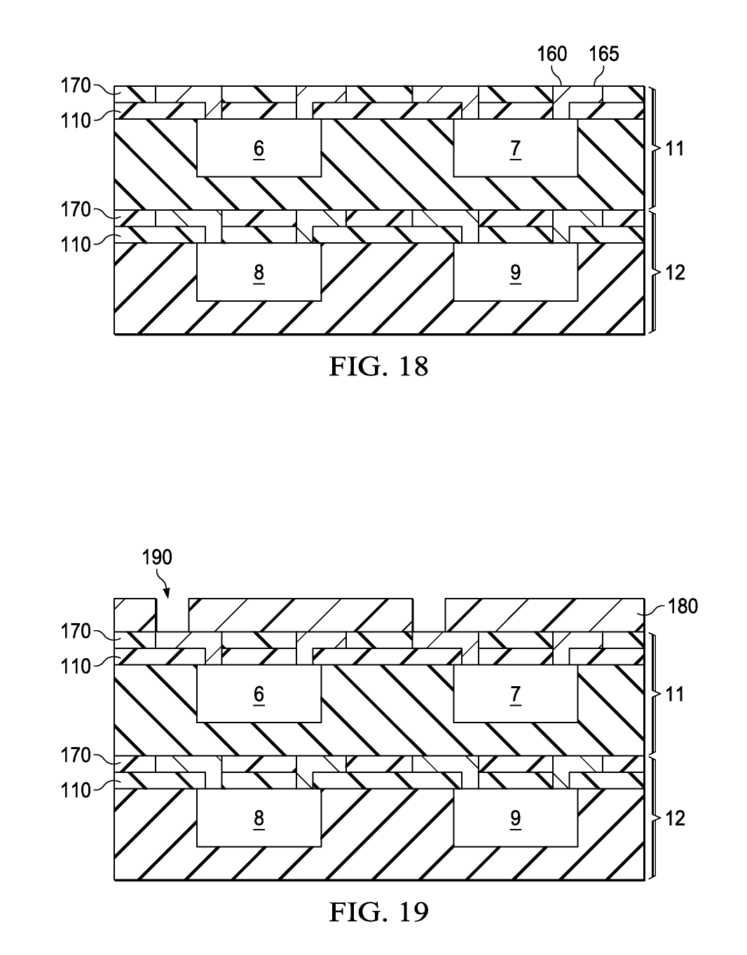

Next, as illustrated in FIG. 18, a plurality of reconstituted wafers are stacked. The reconstituted wafers may be thinned prior to stacking in accordance with an embodiment of the invention. The reconstituted wafer may be stacked back-to-back or alternatively in face-to-back configuration, which is illustrated in FIG. 18.

In one embodiment, a first die 6 is stacked over a third die 8 while a second die 7 is stacked over a fourth die 9. Further, in some embodiments, the first die 6 may be coupled to the second die 7 and/or the third die 8 may be coupled to the fourth die 9. In alternative embodiments, the first die 6 may be stacked partially over the third die 8 and the fourth 9 so as to form a package comprising the first die 6, the third die 8, and the fourth die 9.

After aligning and arranging the first reconstituted wafer 11 over the second reconstituted wafer 12, a joining process may be used. In one embodiment, an intermediate layer bonding may be used. For example, intermediate layers such as an adhesive, epoxy, polymers layers may be applied prior to contacting.

Referring to FIG. 19, as in prior embodiments, a resist 180 may be deposited and patterned forming openings for through via 190.

Using the patterned resist 180 as an etch mask, a through opening 50 may be formed. In one embodiment, the through opening 50 extends through the first reconstituted wafer 11 but not the underlying second reconstituted wafer 12. In an alternative embodiment, the through via 50 extends through both the first and the second reconstituted wafers 11 and 12.

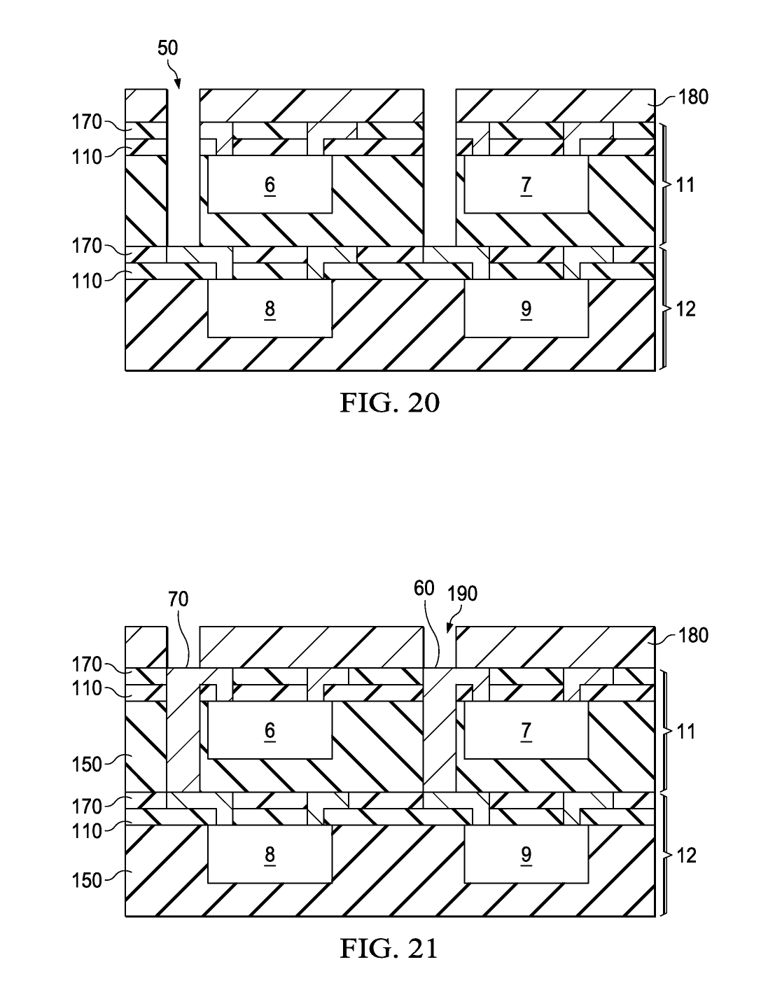

In one embodiment, the through opening 50 is stopped on a landing pad (e.g., embedded contact pad 165) of an underlying reconstituted wafer (FIG. 20). Alternatively, the through opening 50 may extend through both the reconstituted wafers.

As next illustrated in FIG. 21, the through opening 50 is filled with a conductive fill material to form a through via 60. As illustrated one of the through vias 60 couples the first die 6 to the third die 8 while another through via 60 couples the second die 7 with a fourth die 9.

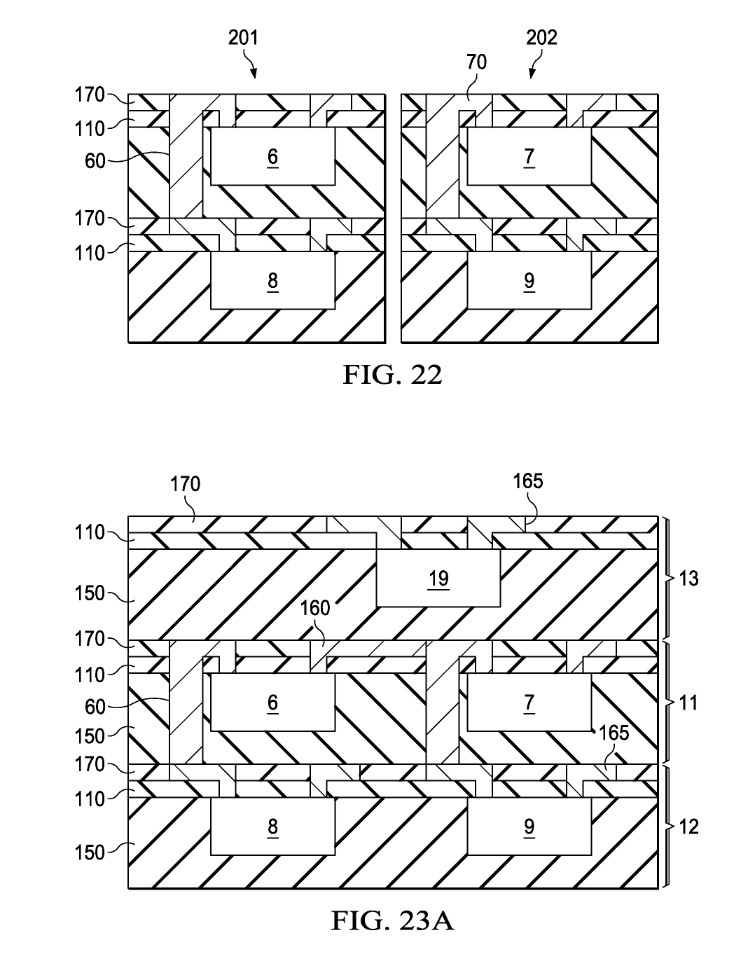

Referring to FIG. 22, the stacked reconstituted wafers may be singulated forming a 3-D integrated chip package.

FIG. 23, which includes FIGS. 23A and 23B, illustrates a further embodiment of forming 3-D integrated fan-out package having a plurality of stacked dies.

This embodiment may follow the method illustrated in FIGS. 12-21. Next, prior to singulation, another wafer, e.g., third wafer 3 having a plurality of dies may be arranged over the stacked wafers as illustrated in FIG. 23A. After placing the third wafer 3 over the stacked wafer, the third wafer 3 may be attached or joined using one of the techniques described above. As illustrated in FIG. 23, the dies of the third wafer 3 may be arranged differently from the first wafer 1 and/or the second wafer 2. Thus, a fifth die 19 is placed over the first die 6 and the second die 7 as illustrated in one case in FIG. 23. In other embodiments, the location of the fifth die 19 may be suitably adjusted.

Referring to FIG. 23B, the third wafer 3 may be coupled to the stacked wafer using a different arrangement of the through vias 60 within the stacked first and second wafers 1 and 2.

FIG. 24, which includes FIGS. 24A-24E, illustrates a further embodiment of forming 3-D integrated packages having a plurality of stacked dies, wherein FIGS. 24A-24D illustrate fan-out packages while FIG. 24E illustrates stacked semiconductor chips.

Referring to FIG. 24A, a third reconstituted wafer 13 is stacked over a first reconstituted wafer 11, which is stacked over a second reconstituted wafer 12. Although described here using the stacking of reconstituted wafers, this embodiment may be applied to stacking of wafers (e.g., first wafer 1, second wafer 2, and third wafer 3 of FIG. 2, e.g., as illustrated below in FIG. 24E).

Next, as illustrated in FIG. 24B, through openings 50 are formed as described in prior embodiments. In one embodiment illustrated in FIG. 24C, the through openings 50 are filled with a conductive material, for example, as described with respect to FIG. 4.

In an alternative embodiment illustrated in FIG. 24D, the through via is partially filed with a conductive material. The remaining portion of the through opening 50 is filled with an insulating fill material to form an insulating plug 65. Thus, one of the through via 60 forms part of the internal circuitry of the 3-D stacked ICs by electrically interconnecting the second reconstituted wafer 12 to the first reconstituted wafer 11.

This embodiment of FIG. 24D may be applied to the embodiments illustrated in FIG. 4A in one or more embodiments as illustrated in FIG. 24E.

FIG. 25 illustrates forming a lead frame package comprising stacked chip in accordance with embodiments of the invention.

In various embodiments, the stacked dies may be packaged using any suitable packaging technology. Examples include flip chip packages, lead frame packages, and others.

FIG. 25 illustrates a leadframe package comprising a leadframe 40 having a plurality of leads 41. The stacked wafers comprising a first die 6 and a second die 7 are stacked over each other and over the leadframe 40. The stacked dies comprising the second die 7 disposed over the first die 6 may be formed according to embodiments of the invention described previously.

Wire bonds 42 may be formed to couple the contact pads disposed on the first die 6 with the plurality of leads 41 of the leadframe 40. The plurality of leads 41 are also coupled to the second die 7 because the contact pads on the first die 6 couple to the second die 7 using the through vias 60.

An encapsulating material 150 is disposed over the leadframe 40 and over the first and the second dies 6 and 7. The encapsulating material 150 may comprise a material as described earlier and may comprise a mold compound, epoxy, and others in various embodiments. The leadframe package may be mounted over a circuit package 45 using solder balls 43.

FIG. 26, which includes FIGS. 26A and 26B, illustrates flip-chip mounting of the stacked dies in various embodiments of the invention.

Referring to FIG. 26A, the contact pads 70 of the stacked dies is prepared for flip chip mounting. As an example, in one embodiment, solder balls 43 may be formed. In various embodiments, in some suitable under bump material may be deposited.

As shown in FIG. 26B, the stacked dies are next mounting on a substrate such as a circuit board 45 using the solder balls, which may be heated to form an eutectic bond with the circuit board 45. In some embodiments, after singulation, the stacked dies may be encapsulated in an encapsulating material 150.

As described in various embodiments, a material that comprises a metal may, for example, be a pure metal, a metal alloy, a metal compound, an intermetallic and others, i.e., any material that includes metal atoms. For example, copper may be a pure copper or any material including copper such as, but not limited to, a copper alloy, a copper compound, a copper intermetallic, an insulator comprising copper, and a semiconductor comprising copper.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. As an illustration, the embodiments described in FIGS. 1-4, FIGS. 5-7, FIGS. 8-10, FIGS. 12-22, FIG. 23, FIG. 24, FIG. 25, and/or FIG. 26 may be combined with each other. It is therefore intended that the appended claims encompass any such modifications or embodiments.

Although the present invention and its advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming a semiconductor device, the method comprising:
stacking a second wafer with a first wafer; and
forming a through via extending through the second wafer while the second wafer is stacked with the first wafer.

2. The method of claim 1, wherein forming the through via comprises:
forming a through hole extending through the second wafer; and
filling the through hole with a conductive material.

3. The method of claim 1, wherein forming the through via comprises:
forming a through hole extending through the first and the second wafers; and
filling the through hole with a conductive material.

4. The method of claim 3, wherein the conductive material comprises a metal.

5. The method of claim 3, wherein the conductive material comprises copper.

6. The method of claim 5, wherein the conductive material comprises pure copper or copper alloys.

7. The method of claim 3, wherein the conductive material comprises poly silicon.

8. The method of claim 3, further comprising:
joining the first wafer with the second wafer before forming the through hole.

9. The method of claim 3, further comprising:
stacking a third wafer with the second wafer; and
stacking a fourth wafer with the third wafer, wherein the through hole extends through the third and the fourth wafers.

10. The method of claim 1, further comprising:
before the stacking, providing a first plurality of dies in the first wafer and a second plurality of dies in the second wafer; and
thinning the first wafer and the second wafer before the stacking.

11. The method of claim 10, wherein the providing comprises forming the first plurality of dies in the first wafer and the second plurality of dies in the second wafer.

12. The method of claim 1, further comprising:
singulating the first and the second wafers after forming the through via.

13. The method of claim 1, wherein the stacking comprises contacting a back side of the first wafer with a back side of the second wafer, wherein a front side of the first wafer and a front side of the second wafer comprise active devices.

14. The method of claim 1, further comprising:
stacking a plurality of wafers with the second wafer, wherein forming the through via comprises forming the through via extending through the plurality of wafers and the second wafer while the plurality of wafers are stacked with the first and the second wafers.

15. A method of forming a semiconductor device, the method comprising:
providing a first reconstituted wafer comprising a first plurality of dies embedded within a first encapsulant;
providing a second reconstituted wafer comprising a second plurality of dies embedded within a second encapsulant;
stacking the first reconstituted wafer with the second reconstituted wafer; and
forming a first through via that extends through second reconstituted wafer while the second reconstituted wafer is stacked with the first reconstituted wafer.

16. The method of claim 15, wherein providing the first reconstituted wafer and providing the second reconstituted wafer comprises forming the first and the second reconstituted wafers.

17. The method of claim 15, wherein the first through via extends through the first reconstituted wafer.

18. The method of claim 15, wherein forming the first through via comprises:
forming a through hole extending through the first and the second reconstituted wafers; and
filling the through hole with a conductive material.

19. The method of claim 15, further comprising singulating the first and the second reconstituted wafers after forming the first through via.

20. The method of claim 15, further comprising:
before forming the first through via, joining the first reconstituted wafer with the second reconstituted wafer to form a stacked reconstituted wafer.

21. The method of claim 15, wherein forming the first through via comprises depositing a conductive material using an electrolytic or electro-less processing.

22. The method of claim 15, further comprising:
forming a third reconstituted wafer comprising a third plurality of dies embedded within a third encapsulant;
stacking the third reconstituted wafer with the second reconstituted wafer after forming the first through via; and
forming a second through via within the third reconstituted wafer.

23. The method of claim 15, further comprising:
forming a third reconstituted wafer comprising a third plurality of dies embedded within a third encapsulant;
stacking the third reconstituted wafer with the second reconstituted wafer before forming the first through via, wherein forming the first through via comprises forming the first through via within the second and the third reconstituted wafers.

24. The method of claim 15, further comprising:
forming a third reconstituted wafer comprising a third plurality of dies embedded within a third encapsulant;
stacking the third reconstituted wafer with the second reconstituted wafer before forming the first through via;
forming a first through opening extending through the second and the third reconstituted wafers;
filling a first portion of the first through opening within the second reconstituted wafer with a conductive material to form the first through via; and
filling a remaining portion of the first through opening with an insulating material.

25. The method of claim 24, further comprising:
forming a second through opening extending through the third reconstituted wafer to a contact on the second reconstituted wafer; and
filling the second through opening with a conductive material.

26. A method of forming a semiconductor device, the method comprising:
singulating a first wafer into a first plurality of dies;
attaching the first plurality of dies over a second wafer comprising a second plurality of dies; and
after attaching, forming a through via extending through a die of the first plurality of dies.

27. The method of claim 26, further comprising:
forming a stacked die by singulating the second wafer.

28. The method of claim 27, further comprising:
placing the stacked die over a lead frame;
forming bonding wires coupling contacts on the second plurality of dies to the lead frame; and
encapsulating the bonding wires, the lead frame, and the stacked die with an encapsulant material.

29. The method of claim 27, wherein the through via extends through the second wafer.

30. The method of claim 27, further comprising:
singulating a third wafer into a third plurality of dies; and
attaching the third plurality of dies over the first plurality of dies, wherein the through via extends through a die of the third plurality of dies.
